(19) United States
(12) Patent Application Publication
(10) Pub. No.: US 2006/0093860 A1
(43) Pub. Date: May 4, 2006

(54) Coated product and method of production thereof

(75) Inventors: Mikael Schuisky, Sandviken (SE); Jens-Petter Palmqvist, Uppsala (SE)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SANDVIK AB, SANDVIKEN (SE)

(21) Appl. No.: 11/023,392

(22) Filed: Dec. 29, 2004

(30) Foreign Application Priority Data
Nov. 4, 2004 (SE) 0402701-7
Nov. 22, 2004 (SE) 0402865-0

(51) Int. Cl. B32B 15/04; B32B 9/00; C23C 14/00

(52) U.S. Cl. 428/698; 428/457; 427/248.1; 204/192.15

(57) ABSTRACT

A coated product is disclosed consisting of a metallic substrate and a coating of a MAX material type. Furthermore, a method of producing such a coated product is disclosed using vapor deposition technique in a continuous roll to roll process.

### RELATED APPLICATION DATA

This application is based on and claims priority under 35 U.S.C. §119 to Swedish Application No. 0402701-7, filed Nov. 4, 2004, the entire contents of which are incorporated herein by reference. This application is also based on and also claims priority under 35 U.S.C. §119 to Swedish Application No. 0402865-0, filed Nov. 22, 2004, the entire contents of which are incorporated herein by reference.

### FIELD OF THE DISCLOSURE

The present disclosure relates to a coated product, such as a coated strip, which consists of a metallic substrate and a coating of a so called MAX material. Furthermore, the present disclosure relates to the manufacturing of such a coated product.

### STATE OF THE ART

A MAX material is a ternary compound with the following formula Mₙ₊₁A_{z}Xₙ. M is at least one transition metal selected from the group of Ti, Sc, V, Cr, Zr, Nb, Ta; A is at least one element selected from the group consisting of Si, Al, Ge and/or Sn; and X is at least one of the non-metals C and/or N. The ranges of the different components of the single phase material is determined by n and z, wherein n is within the range of 0.8 l to 3.2 and z is within the range of 0.8 to 1.2. Consequently, examples of compositions within the MAX material group are Ti₃SiC₂, Ti₂AIC, Ti₂AIN and Ti₂SnC.

MAX materials may be used in several different environments. These materials have among other properties a good electrical conductivity, are high temperature resistant, have high corrosion resistance as well as low friction and are relatively ductile. Some MAX materials are also known to be bio-compatible. Consequently, MAX materials and coatings of MAX materials on metallic substrates are well suited for use as, for example, electrical contact materials in corrosive environments and at high temperatures, wear resistant contact materials, low friction surfaces in sliding contacts, interconnects in fuel cells, coatings on implants, decorative coatings and non-sticking surfaces, just to name a few.

It is previously known to accomplish articles coated with MAX materials in batch processes, see for example WO 03046247 A1. However, such processes do not produce a cost effective material and uses fairly advanced technology by for example utilizing a seed layer. Therefore, there is a need of a process to produce a cost effective substrate material with a dense coating of MAX material.

Consequently, it is an object of the present invention to manufacture a substrate coated with a MAX material in a cost effective manner while at the same time accomplish a dense MAX material coating with a good adhesion to the substrate.

### SUMMARY

An exemplary method of coating of a metal substrate with a coating having a composition of Mₙ₊₁A_{z}Xₙ is disclosed. The exemplary method comprises, coating a metal substrate with a coating having a composition of Mₙ₊₁A_{z}Xₙ, wherein M is at least one metal selected from the group of Ti, Sc, V, Cr, Zr, Nb, Ta; A is at least one element selected from the group consisting of Si, Al, Ge and/or Sn; and X is at least one of the non-metals C and/or N, n is within the range of 0.8 to 3.2 and z is within the range of 0.8 to 1.2. The coating is coated coated onto the surface of the substrate continuously by usage of vapor phase deposition technique.

Another exemplary method of coating of a metal substrate comprises coating a surface of the metal substrate with a coating having a composition of Mₙ₊₁A_{z}Xₙ, wherein M is at least one metal selected from the group of Ti, Sc, V, Cr, Zr, Nb, Ta; A is at least one element selected from the group consisting of Si, Al, Ge and Sn; and X is at least one of non-metal selected from the group consisting of C and N, n is 0.8 to 3.2 and z is 0.8 to 1.2, wherein coating is provided continuously by a vapor phase deposition technique.

An exemplary embodiment of a coated product consists of a metal substrate and a coating, the coating having a composition of Mₙ₊₁A_{z}Xₙ, wherein M is at least one transition metal selected from the group of Ti, Sc, V, Cr, Zr, Nb, Ta; A is at least one element selected from the group consisting of Si, Al, Ge and/or Sn; and X is at least one of the non-metals C and/or N, wherein n is within the range of 0.8 to 3.2 and z is within the range of 0.8 to 1.2, wherein the metal substrate is at least 10 meters long. A coated product consists of a metal substrate, wherein the metal substrate is at least 10 meters long, and a coating on a surface of the metal substrate, the coating having a composition of Mₙ₊₁A_{z}Xₙ, wherein M is at least one transition metal selected from the group of Ti, Sc, V, Cr, Zr, Nb, Ta; A is at least one element selected from the group consisting of Si, Al, Ge and Sn; and X is at least one of non-metal selected from the group consisting of C and N, wherein n is 0.8 to 3.2 and z is 0.8 to 1.2.

### DETAILED DESCRIPTION OF PREFERRED EMBODIMENTS

A substrate coated with MAX material is produced in a continuous roll-to-roll process whereby, among other properties, a good adhesion of the coating over the total surface of the substrate is accomplished. In this context a good adhesion is considered to mean that the product is able to be bent at least 90 degrees over a radius equal to the thickness of the substrate without showing any tendency to flaking, spalling or the like, of the coating.

The composition of the substrate material could be any metallic material. Typically, substrate material is selected from the group consisting of Fe, Cu, Al, Ti, Ni, Co and alloys based on any of these elements, but other substrate materials, such as those typically selected for the application can be used. Some examples of suitable materials to be used as substrates are ferritic chromium steels of the Type AISI 400-series, austenitic stainless steels of the type AISI 300-series, hardenable chromium steels, duplex stainless steels, precipitation hardenable steels, cobalt alloyed steels, Ni based alloys or alloys with a high content of Ni, and Cu based alloys. According to a preferred embodiment, the substrate is a stainless steel with a chromium content of at least 10% by weight.

The substrate may be in any condition, such as soft annealed, cold-rolled or hardened condition as long as the substrate is able to withstand the coiling on the rolls of the production line.

The substrate is a metallic substrate material in the form of a strip, foil, wire, fiber, tube or the like. According to a preferred embodiment, the substrate is a in the form of a strip or foil.

The length of the substrate is at least 10 meters in order to ensure a cost effective coated product. Preferably, the length is at least 50 meters and most preferably at least 100 meters. In fact, the length might be up to at least 20 km, and for certain product forms such as fibers, it might be even much longer.

The thickness of the substrate when in the form of a strip or foil is usually at least 0.015 mm thick, preferably at least 0.03 mm, and up to 3.0 mm thick, preferably maximally 2 mm. The most preferred thickness is within the range of 0.03 to 1 mm. The width of the strip is usually between 1 mm and 1500 mm. However, according to a preferred embodiment the width is at least 5 mm, but at the most 1 m.

The composition of the MAX material coating is Mₙ₊₁A_{z}Xₙ. M is at least one transition metal selected from the group of Ti, Sc, V, Cr, Zr, Nb, Ta; A is at least one element selected from the group consisting of Si, Al, Ge and/or Sn; and X is at least one of the non-metals C and/or N. The ranges of the different components of the single phase material is determined by n and z, wherein n is within the range of 0.8 to 3.2 and z is within the range of 0.8 to 1.2.

The crystallinity of the coating may vary from amorphous or nanocrystalline to well-crystallised and near single phase material. Naturally, this can be accomplished by control of temperature or other process parameters during growth of the coating, i.e. during deposition. For example, a higher temperature during deposition of the coating may render a coating of a higher crystallinity. According to different embodiments, the crystallinity may be substantially single phased, amorphous and/or crystalline. By substantially is meant that other forms of crystallinity is merely present in amounts not effecting the properties of the coating.

The coating has a thickness adapted to the usage of the coated product. However, it is preferred that the thickness of the coating is at least 5 nm, preferably at least 10 nm; and not more than 25 μm, preferably not more than 10 μm, most preferably not more than 5 μm. Suitable thicknesses usually fall within the range of 50 nm to 2 μm.

The substrate may be provided with the coating by any method resulting in a dense and adherent coating. In one example the coating is performed using vapor phase deposition technique in a continuous roll to roll process. Vapor deposition technique includes CVD processes as well as PVD processes. Examples of applicable PVD processes are magnetron sputtering and electron beam evaporation. The electron beam evaporation process can be both plasma activated and/or reactive, if needed, in order to form a dense and well adherent layer.

Naturally, the surface of the substrate has to be cleaned in a proper way before coating, for example to remove oil residues and/or the native oxide layer of the substrate.

An advantage of the use of PVD technique is that the substrate material is not heated as much as would be required during for example a CVD process. Consequently, the risk of deterioration of the substrate material during coating is reduced. Deterioration of the substrate may be further prevented with the aid of controlled cooling of the substrate during coating.

In a continuous process, the substrate speed during coating is at least 1 meters/minute; preferably the substrate speed is at least 3 meters/minute and most preferably at least 10 meters/minute. The high speed contributes to producing the product in a cost effective way. Furthermore, high speed also reduces the risk of deterioration of the substrate material whereby a higher quality of the product may be achieved.

In the case where the substrate is a strip or foil, it may be provided with a coating on one side or on both sides. In the case the coating is provided on both surfaces of the strip, the composition of the coatings on each side of the strip may be the same but may also differ depending on the application in which the coated product will be used. The strip may be coated on both sides simultaneously or on one side at a time.

The coating may, for example, be produced by vaporizing a target of a MAX material and depositing onto the substrate according to the definition stated above. The coating may be produced in several coating chambers located in line, but it may also be produced in one single chamber.

In some cases, it might be applicable to provide an optional thin bonding layer between metal substrate and the coating in order to further improve the adhesion of the coating. The bonding layer may, for example, be based on one of the metals from the MAX material, but also other metallic materials may be used as bonding layer. The bonding layer is preferably as thin as possible, not more than 50 nm, preferably not more than 10 nm. The bonding layer may be applied by any conventional method such as vapor deposition processes, electrochemical process etc.

In the case where the substrate is a strip or foil, an alternative embodiment has one surface of the substrate coated with a MAX material while the other surface is coated with a different material, for example a non-conductive material or a material which will improve soldering, such as Sn or Ni. In these cases, the MAX coating may be applied to one side of the substrate and for example an electrically isolating material such as Al₂O₃ or SiO₂ may be applied to the other side of the substrate. This may be done in-line with the coating of MAX material in separate chambers, or it may be done at separate occasions.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

What is claimed is:

1. A method of coating of a metal substrate with a coating having a composition of Mₙ₊₁A_{z}Xₙ wherein M is at least one metal selected from the group of Ti, Sc, V, Cr, Zr, Nb, Ta; A is at least one element selected from the group consisting of Si, Al, Ge and/or Sn; and X is at least one of the non-metals C and/or N, n is within the range of 0.8 to 3.2 and z is within the range of 0.8 to 1.2, is coated onto the surface of the substrate wherein the coating is provided continuously by usage of vapor phase deposition technique.

2. The method according to claim 1, wherein the vapor phase deposition technique is magnetron sputtering.

3. The method according to claim 2, wherein the coating process is performed in a roll-to-roll process.

4. The method according to claim 1, wherein the vapor phase deposition technique is electron beam evaporation.

5. The method according to claim 4, wherein the electron beam evaporation is plasma activated and/or reactive.

6. The method according to claim 1, wherein the coating process is performed in a roll-to-roll process.

7. The method according to claim 1, wherein the substrate is provided in a length of at least 10 meters.

8. The method according to claim 1, wherein a target having the following composition Mₙ₊₁A_{z}Xₙ, wherein M is at least one transition metal selected from the group of Ti, Sc, V, Cr, Zr, Nb, Ta; A is at least one element selected from the group consisting of Si, Al, Ge and/or Sn; and X is at least one of the non-metals C and/or N, wherein n is within the range of 0.8 to 3.2 and z is within the range of 0.8 to 1.2 is produced and inserted in at least one coating chamber and thereafter vaporized in order to produce at least a part of the coating.

9. The method according to claim 1, wherein a bonding layer is provided on the substrate before the coating process with the coating.

10. A coated product consisting of a metal substrate and a coating, the coating having a composition of Mₙ₊₁A_{z}Xₙ, wherein M is at least one transition metal selected from the group of Ti, Sc, V, Cr, Zr, Nb, Ta; A is at least one element selected from the group consisting of Si, Al, Ge and/or Sn; and X is at least one of the non-metals C and/or N, wherein n is within the range of 0.8 to 3.2 and z is within the range of 0.8 to 1.2, wherein the metal substrate is at least 10 meters long.

11. The coated product according to claim 10, wherein the coating is substantially single phased.

12. The coated product according to claim 10, wherein the coating is substantially amorphous.

13. The coated product according to claim 10, wherein the coating is substantially crystalline.

14. The coated product according to claim 10, wherein a bonding layer is located between the substrate and the coating.

15. A method of coating of a metal substrate, the method comprising:
coating a surface of the metal substrate with a coating having a composition of Mₙ₊₁A_{z}Xₙ wherein M is at least one metal selected from the group of Ti, Sc, V, Cr, Zr, Nb, Ta; A is at least one element selected from the group consisting of Si, Al, Ge and Sn; and X is at least one of non-metal selected from the group consisting of C and N, n is 0.8 to 3.2 and z is 0.8 to 1.2,
wherein coating is provided continuously by a vapor phase deposition technique.

16. A coated product, consisting of:
a metal substrate, wherein the metal substrate is at least 10 meters long; and
a coating on a surface of the metal substrate, the coating having a composition of Mₙ₊₁A_{z}Xₙ, wherein M is at least one transition metal selected from the group of Ti, Sc, V, Cr, Zr, Nb, Ta; A is at least one element selected from the group consisting of Si, Al, Ge and Sn; and X is at least one of non-metal selected from the group consisting of C and N, wherein n is 0.8 to 3.2 and z is 0.8 to 1.2.
